(19) United States
(12) Patent Application Publication
(10) Pub. No.: US 2017/0077122 A1
(43) Pub. Date: Mar. 16, 2017

(54) INTEGRATED CIRCUIT DEVICE AND METHOD FOR MANUFACTURING SAME

(71) Applicant: Kabushiki Kaisha Toshiba, Minato-ku (JP)

(72) Inventor: Takatoshi ONO, Yokkaichi (JP)

(73) Assignee: Kabushiki Kaisha Toshiba, Minato-ku (JP)

(21) Appl. No.: 14/978,615

(22) Filed: Dec. 22, 2015

(30) Foreign Application Priority Data
Sep. 10, 2015 (JP) 2015-178919

(51) Int. Cl. H01L 27/115

(52) U.S. Cl. CPC H01L 27/11582; H01L 27/11568

(57) ABSTRACT

A method for manufacturing an integrated circuit device includes forming a first film on a foundation member. A recess is made in a surface of the foundation member. An upper surface of a portion of the first film is positioned lower than an upper surface of a portion of the foundation member at a periphery of the recess. The method includes forming a second film on the first film. An upper surface of the entire portion of the second film is positioned higher than the upper surface of the foundation member at the periphery. The method includes removing portions of the second film and the first film positioned higher than the upper surface of the foundation member at the periphery by performing planarization on a condition causing a polishing rate of the first film to be higher than a polishing rate of the second film.

### CROSS-REFERENCE TO RELATED APPLICATIONS

This application is based upon and claims the benefit of priority from Japanese Patent Application No. 2015-178919, filed on Sep. 10, 2015; the entire contents of which are incorporated herein by reference.

### FIELD

Embodiments relate to an integrated circuit device and a method for manufacturing the same.

### BACKGROUND

In recent years, to realize higher integration of memory cells in a semiconductor memory device, a stacked type semiconductor memory device has been proposed. The stacked type semiconductor memory device has a stacked body in which multiple electrode films are stacked, and the memory cells are arranged three-dimensionally in the stacked body. To draw out the electrode films from the memory cells in such a stacked semiconductor memory device, a recess that has a valley-like configuration is made in the stacked body, and the electrode films are exposed at the side surface of the recess. An inter-layer insulating film is filled into the recess.

### BRIEF DESCRIPTION OF THE DRAWINGS

FIG. 1 is a cross-sectional view showing an integrated circuit device according to a first embodiment;

FIGS. 2A to 4B are cross-sectional views showing a method for manufacturing the integrated circuit device according to the first embodiment;

FIGS. 5A and 5B are cross-sectional views showing a method for manufacturing an integrated circuit device according to a comparative example;

FIG. 6 is a cross-sectional view showing an integrated circuit device according to a second embodiment;

FIG. 7 is a cross-sectional view showing region A of FIG. 6, and

FIG. 8 to FIG. 10 are cross-sectional views showing a method for manufacturing the integrated circuit device according to the second embodiment.

### DETAILED DESCRIPTION

A method for manufacturing an integrated circuit device according to an embodiment includes forming a first film on a foundation member. A recess is made in a surface of the foundation member. An upper surface of one section of a portion of the first film is positioned lower than an upper surface of a portion of the foundation member at a periphery of the recess. The portion is disposed in a region directly above the recess. The method includes forming a second film on the first film. An upper surface of the entire portion of the second film disposed in the region directly above the recess is positioned higher than the upper surface of the portion of the foundation member at the periphery of the recess. The method includes removing portions of the second film and the first film positioned higher than the upper surface of the portion of the foundation member at the periphery of the recess by performing planarization of the second film and the first film on a condition causing a polishing rate of the first film to be higher than a polishing rate of the second film.

### First Embodiment

First, a first embodiment will be described.

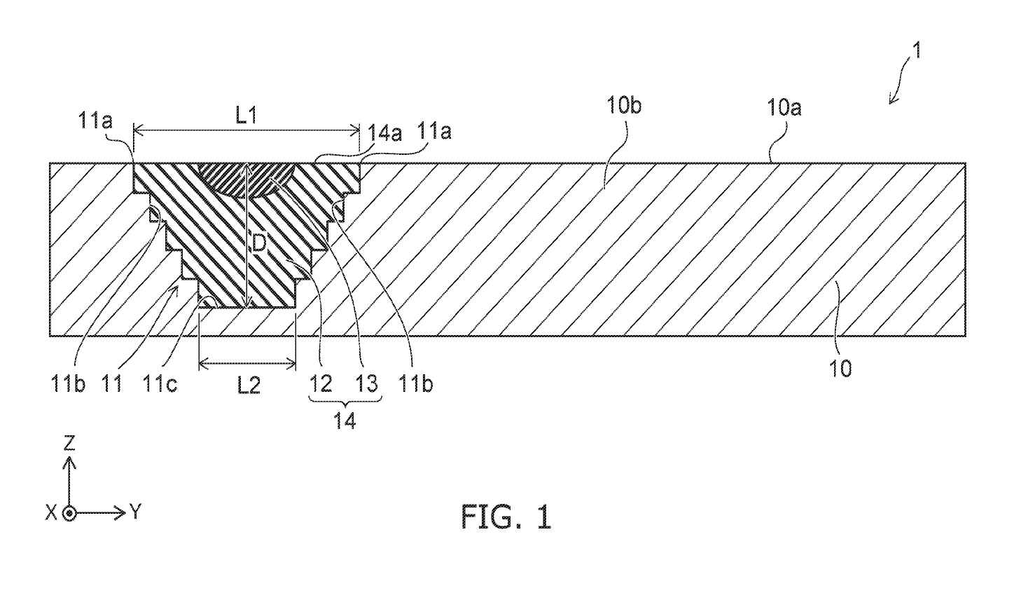

FIG. 1 is a cross-sectional view showing an integrated circuit device according to the embodiment.

The following drawings are schematic; and the dimensional ratios of the components are not necessarily precise. Also, the dimensional ratios do not necessarily match between the drawings.

As shown in FIG. 1, a foundation member 10 is provided in the integrated circuit device 1 according to the embodiment. The configuration of the foundation member 10 is substantially a plate configuration. An integrated circuit is formed inside the foundation member 10. Hereinbelow, an XYZ orthogonal coordinate system is employed for convenience of description in the specification. Two mutually-orthogonal directions parallel to an upper surface 10a of the foundation member 10 are taken as an “X-direction” and a “Y-direction;” and a direction perpendicular to the upper surface 10a of the foundation member 10 is taken as a “Z-direction.”

A recess 11 that has a valley-like configuration extending in the X-direction is made in the surface of the foundation member 10. The direction in which a pair of upper end portions 11a of a recess 11 are separated is the Y-direction. The configuration of a side surface 11b of the recess 11 facing the Y-direction is a stairstep configuration. Therefore, a distance L1 between the upper end portions 11a of the recess 11 is longer than a length L2 in the Y-direction of a bottom surface 11c of the recess 11. In other words, L1>L2. The distance L1 is, for example, several mm (millimeters). A depth D of the recess 11 is, for example, about 1 μm (micrometers). The upper surface 10a of a portion 10b of the foundation member 10 other than the recess 11 is substantially flat.

A silicon oxide film (a first film) 12 that has silicon oxide as a major component is provided inside the recess 11. A silicon oxide film (a second film) 13 that has silicon oxide as a major component is provided on the central portion of the silicon oxide film 12. For example, the silicon oxide film 12 is formed by coating using PSZ (polysilazane) as a material. For example, the silicon oxide film 13 is formed by CVD (Chemical Vapor Deposition) using d-TEOS (Tetra Ethyl Ortho Silicate (Si(OC₂H₅)₄)) as a source material.

Although impurities are not added deliberately to the silicon oxide film 12 and the silicon oxide film 13, impurities due to the film formation processes are included. For example, the carbon concentration of the silicon oxide film 13 is higher than the carbon concentration of the silicon oxide film 12. For example, the carbon concentration of the silicon oxide film 12 is lower than 1×10²⁰ atoms/cm³; and the carbon concentration of the silicon oxide film 13 is higher than 1×10²⁰ atoms/cm³. Also, the polishing rate of the silicon oxide film 12 is higher than the polishing rate of the silicon oxide film 13 when performing CMP (Chemical Mechanical Polishing). Generally, there is a positive correlation between the polishing rate of CMP and the etching rate of wet etching. Accordingly, if wet etching is performed, the etching rate of the silicon oxide film 12 is higher than the etching rate of the silicon oxide film 13. Therefore, the likelihood is high that the interface between the silicon oxide film 12 and the silicon oxide film 13 can be observed when wet etching of the cross section of the integrated circuit device 1 shown in FIG. 1 is performed.

An inter-layer insulating film 14 is formed of the silicon oxide film 12 and the silicon oxide film 13. The inter-layer insulating film 14 is disposed inside the recess 11 to fill the recess 11. The inter-layer insulating film 14 is not disposed on the portion 10b of the foundation member 10 other than the recess 11. An upper surface 14a of the inter-layer insulating film 14 is a continuous surface and has the same position as the upper surface 10a of the portion 10b of the foundation member 10 at the periphery of the recess 11 or is positioned lower than the upper surface 10a.

A method for manufacturing the integrated circuit device according to the embodiment will now be described.

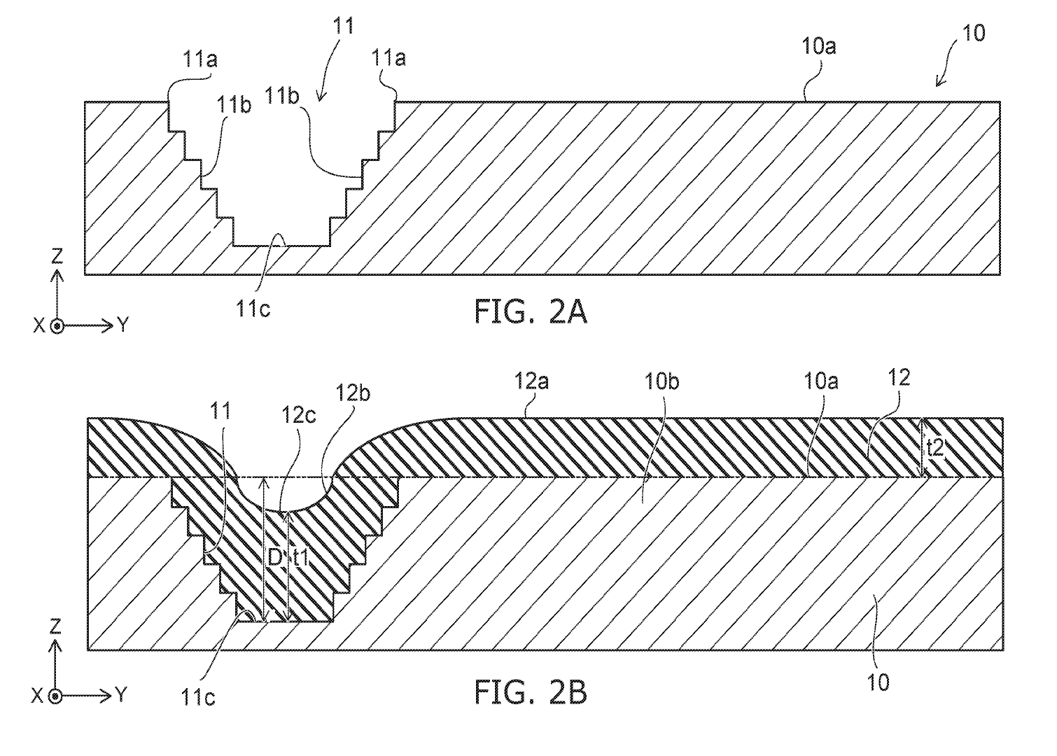

FIGS. 2A and 2B, FIGS. 3A and 3B, and FIGS. 4A and 4B are cross-sectional views showing the method for manufacturing the integrated circuit device according to the embodiment.

First, the foundation member 10 is prepared as shown in FIG. 2A. The recess 11 is made in the surface of the foundation member 10. The configuration of the recess 11 is as described above.

Then, as shown in FIG. 2B, the silicon oxide film 12 is formed by coating PSZ on the foundation member 10 and by performing heat treatment. The configuration of an upper surface 12a of the silicon oxide film 12 reflects the configuration of the surface of the foundation member 10; and a recess 12b is made in the region directly above the recess 11. However, the depth of the recess 12b is shallower than the recess 11 due to the flow of the coating material. In other words, a thickness t1 of the portion of the silicon oxide film 12 disposed on the bottom surface 11c of the recess 11 is thicker than a thickness t2 of the portion of the silicon oxide film 12 disposed in the region where the recess 11 is not made.

However, the thickness t1 is thinner than the depth D of the recess 11. In other words, D>t1>t2. Thereby, an upper surface 12c of one section of the portion of the silicon oxide film 12 disposed in the region directly above the recess 11 is positioned lower than the upper surface 10a of the portion 10b of the foundation member 10 at the periphery of the recess 11. The thickness t2 is, for example, 0.5 μm.

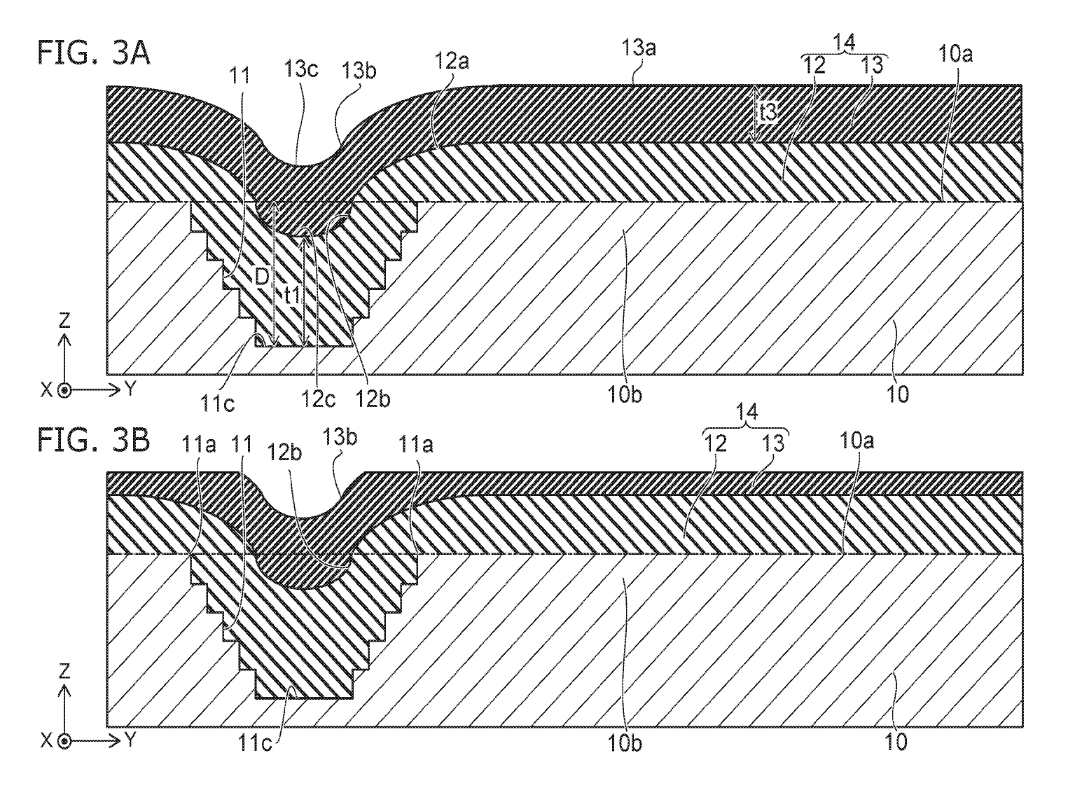

Then, as shown in FIG. 3A, the silicon oxide film 13 is formed on the silicon oxide film 12 by CVD using d-TEOS as a source material. The configuration of an upper surface 13a of the silicon oxide film 13 reflects the configuration of the upper surface 12a of the silicon oxide film 12; and a recess 13b is made in the region directly above the recess 11. Because the silicon oxide film 13 is formed by CVD, the thickness of the silicon oxide film 13 is substantially uniform. Accordingly, the depth of the recess 13b is substantially equal to the depth of the recess 12b. Also, because the recess 12b is made in the region of the upper surface 12a of the silicon oxide film 12 directly above the recess 11, the portion of the silicon oxide film 13 disposed in the region directly above the recess 11 is positioned lower than the portion of the silicon oxide film 13 disposed in the region directly above the portion 10b.

A thickness t3 of the silicon oxide film 13 is set to be thicker than the difference (D−t1) between the depth D of the recess 11 and the thickness t1 of the portion of the silicon oxide film 12 disposed inside the recess 11. In other words, t3>D−t1. Thereby, an upper surface 13c of the entire portion of the silicon oxide film 13 disposed in the region directly above the recess 11 is positioned higher than the upper surface 10a of the portion 10b of the foundation member 10 at the periphery of the recess 11. For example, the thickness t3 is 1 to 1.5 μm. As described above, the carbon concentration of the silicon oxide film 13 is higher than the carbon concentration of the silicon oxide film 12. The inter-layer insulating film 14 includes the silicon oxide film 12 and the silicon oxide film 13.

Then, as shown in FIG. 3B, planarization, e.g., CMP, of the inter-layer insulating film 14 is performed. The object of the CMP is to completely remove the inter-layer insulating film 14 that is on the portion 10b of the foundation member 10 other than the recess 11 while causing the inter-layer insulating film 14 that has a substantially flat upper surface to remain inside the recess 11. At this time, the conditions of the CMP are such that the polishing rate of the silicon oxide film 12 is higher than the polishing rate of the silicon oxide film 13. Because the silicon oxide film 12 is formed by coating and the silicon oxide film 13 is formed by CVD, the film properties of the silicon oxide film 12 are rougher than the film properties of the silicon oxide film 13. Therefore, it is easy to realize such conditions.

Generally, in CMP, the member to be polished is not polished perfectly in a plane from the upper portion toward the lower portion; and the exposed portion of the lower portion also is undesirably polished somewhat at the stage where the upper portion remains. Therefore, in the case where an unevenness is formed in the upper surface of the member to be polished, the unevenness cannot be eliminated completely, even by polishing only an amount that corresponds to the difference between highs and lows of the unevenness. Accordingly, in the case where the unevenness in the initial state is sufficiently large, the unevenness may undesirably remain in the upper surface of the member to be polished even at the point in time when the CMP ends; and such a tendency becomes high particularly when the planar dimensions of the recess and/or the flat portion at the recess periphery are large.

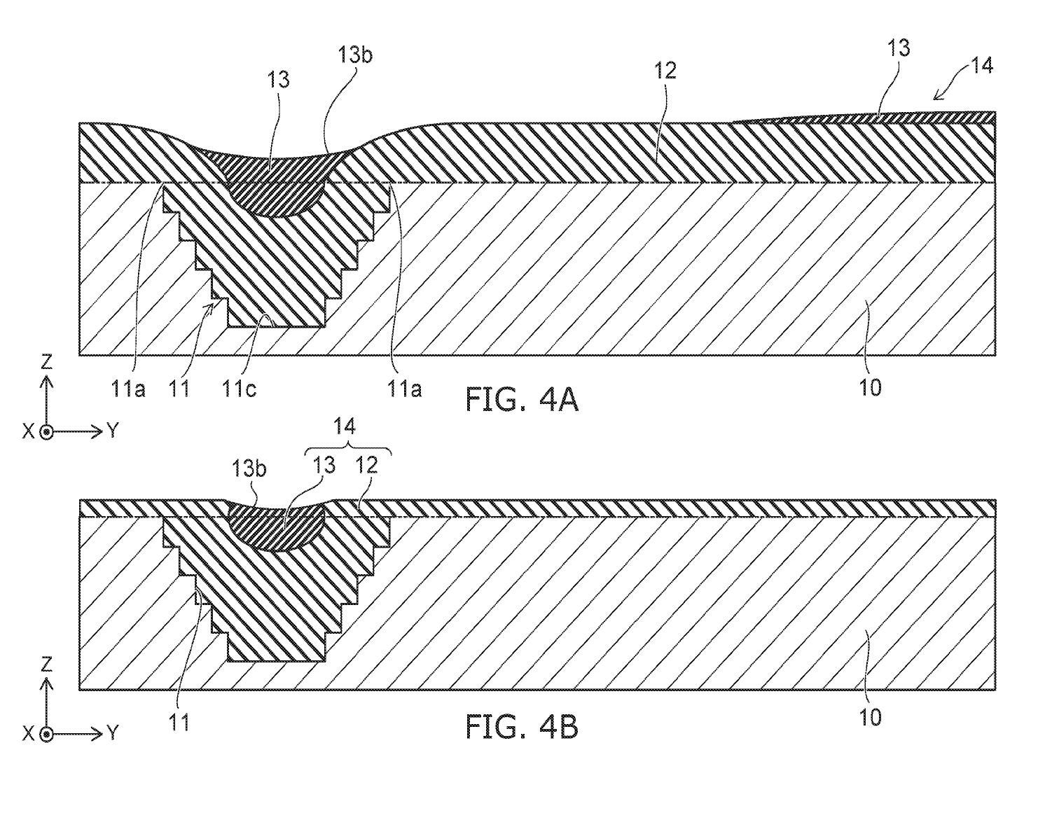

Therefore, as shown in FIG. 3B, the silicon oxide film 13 that is on the upper layer side is polished from the upper surface side in the initial stage of the CMP. However, as the CMP continues, because the stepped portion, i.e., the portion of the silicon oxide film 13 disposed at the vicinity of the upper end portion 11a of the recess 11, is polished preferentially to the other portions, the portion of the silicon oxide film 13 disposed at the vicinity of the upper end portion 11a of the recess 11 is consumed initially and the silicon oxide film 12 is exposed as shown in FIG. 4A. At this time, the silicon oxide film 13 remains on the region directly above the bottom surface 11c of the recess 11 and on the portion of the foundation member 10 distal to the recess 11.

Because the polishing rate of the silicon oxide film 12 is higher than the polishing rate of the silicon oxide film 13, once the silicon oxide film 12 is exposed, the silicon oxide film 12 is polished at a rate that is higher than that of the silicon oxide film 13 as shown in FIG. 4B; and the thickness of the inter-layer insulating film 14 is made to be uniform. In other words, the recess 13b becomes shallow by removing the silicon oxide film 12 of the periphery of the recess 11 while causing the silicon oxide film 13 to remain in the region directly above the recess 11. Then, as shown in FIG. 1, the CMP is stopped when the inter-layer insulating film 14 that is on the portion 10b of the foundation member 10 other than the recess 11 is removed. Thus, the integrated circuit device 1 according to the embodiment is manufactured.

Effects of the embodiment will now be described.

In the embodiment, the silicon oxide film 12 is formed by coating on the foundation member 10 in which the recess 11 is made in the process shown in FIG. 2B; and the silicon oxide film 13 is formed by CVD on the silicon oxide film 12 in the process shown in FIG. 3A. Therefore, a high polishing rate ratio can be realized between the silicon oxide film 12 and the silicon oxide film 13. Specifically, the polishing rate of the silicon oxide film 12 can be set to be higher than the polishing rate of the silicon oxide film 13. Then, CMP is performed in the processes shown in FIG. 3B to FIG. 4B.

At this time, because the configuration of the silicon oxide film 12 reflects the recess 11, the portion of the silicon oxide film 13 disposed in the region directly above the recess 11 is positioned lower than the portion of the silicon oxide film 13 disposed above the portion 10b of the foundation member 10 other than the recess 11. Therefore, partway through the CMP, the silicon oxide film 12 at the vicinity of the upper end portion 11a of the recess 11 is exposed in the state in which the silicon oxide film 13 remains at one section of the region directly above the recess 11. Then, because the polishing rate of the silicon oxide film 12 is higher than the polishing rate of the silicon oxide film 13, the silicon oxide film 12 disposed in the region of the periphery of the recess 11 is polished preferentially to the silicon oxide film 13 disposed in the region directly above the recess 11; and the upper surface 14a of the inter-layer insulating film 14 is planarized. As a result, as shown in FIG. 1, even without excessively over-polishing the silicon oxide film 13, the portion 10b of the foundation member 10 other than the recess 11 can be completely exposed easily; and the inter-layer insulating film 14 of which the upper surface 14a is substantially flat can be filled into the recess 11. Thereby, the upper surface of the structure body including the foundation member 10 and the inter-layer insulating film 14 can be substantially flat.

Thus, according to the embodiment, even for the recess 11 that is wide and deep and has a width of about several mm and a depth of about 1 μm, the inter-layer insulating film 14 of which the upper surface 14a is substantially flat can be filled without the silicon oxide film 12 remaining outside the recess 11. Thereby, the process precision of subsequent manufacturing processes increases. For example, the focus of the exposure in lithography processes can be aligned with high precision. Thus, according to the embodiment, a method for manufacturing an integrated circuit device having high shape precision can be realized.

Although an example is illustrated in the embodiment in which the silicon oxide film 12 is formed by coating, this is not limited thereto; and it is sufficient for the polishing rate of the silicon oxide film 12 to be higher than the polishing rate of the silicon oxide film 13. For example, the silicon oxide film 12 may be formed by depositing NSG (non-doped silicate glass) by CVD. Also, for example, a third film that has a polishing rate higher than that of the silicon oxide film 13 may be further stacked on the silicon oxide film 13 to relax the unevenness of the surface after forming the silicon oxide film 13; and subsequently, CMP of the third film and the inter-layer insulating film 14 may be performed.

### COMPARATIVE EXAMPLE

A comparative example will now be described.

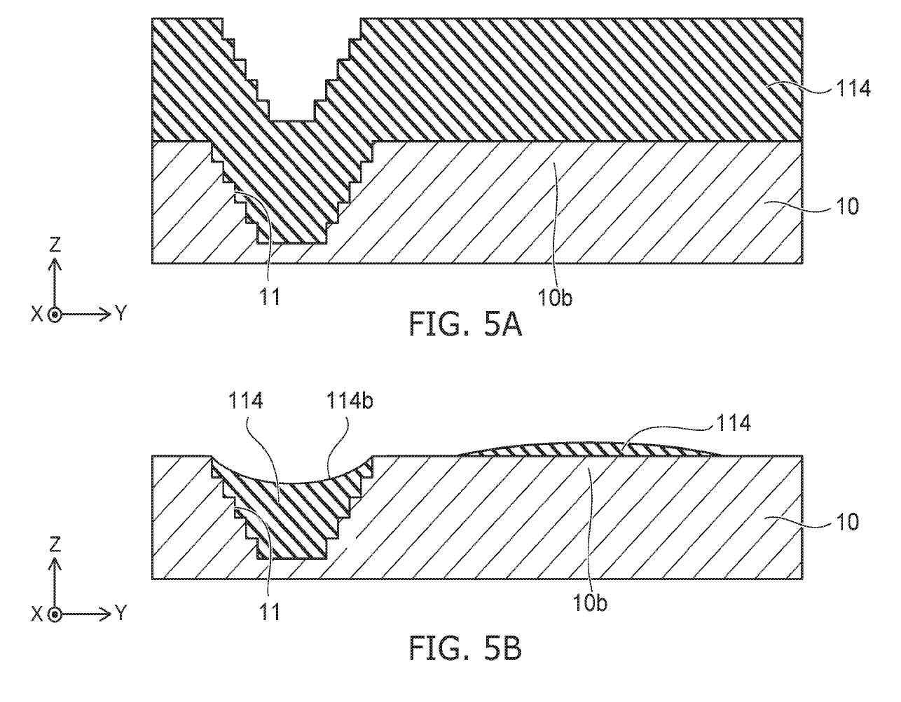

FIGS. 5A and 5B are cross-sectional views showing a method for manufacturing an integrated circuit device according to the comparative example.

First, as shown in FIG. 5A, a single-layer silicon oxide film 114 is formed on the foundation member 10 having the recess 11 made in the upper surface. The silicon oxide film 114 is formed to completely fill the recess 11.

Then, CMP of the silicon oxide film 114 is performed as shown in FIG. 5B. The object of the CMP is to completely expose the portion 10b of the foundation member 10 other than the recess 11 and cause the silicon oxide film 114 to remain inside the recess 11 in a state in which the upper surface of the silicon oxide film 114 is flat. However, at this time, the silicon oxide film 114 is not polished perfectly in a plane from the upper portion toward the lower portion; and the exposed portion of the lower portion is undesirably polished somewhat at the stage where the upper portion remains. Therefore, even after the CMP has progressed, the initial configuration of the upper surface of the silicon oxide film 114 undesirably remains. In other words, a recess 114b is undesirably made in the upper surface of the silicon oxide film 114 remaining inside the recess 11 in a state in which the silicon oxide film 114 remains on the central portion of the portion 10b of the foundation member 10 other than the recess 11. In particular, in the case where the planar dimension of the portion 10b of the foundation member 10 other than the recess 11 is large, excessive over-polish is necessary to completely remove the silicon oxide film 114 remaining on the portion 10b; dishing of the recess 114b occurs; and the recess 114b undesirably becomes deep. On the other hand, in the case where the CMP is stopped in a state in which the polishing is insufficient so that the upper surface of the silicon oxide film 114 remaining inside the recess 11 is flat and the recess 114b is not made, a thicker silicon oxide film 114 undesirably remains on the portion 10b. Thus, in the comparative example, it is difficult to make a flat upper surface of the structure body including the foundation member 10 and the silicon oxide film 114.

### Second Embodiment

A second embodiment will now be described.

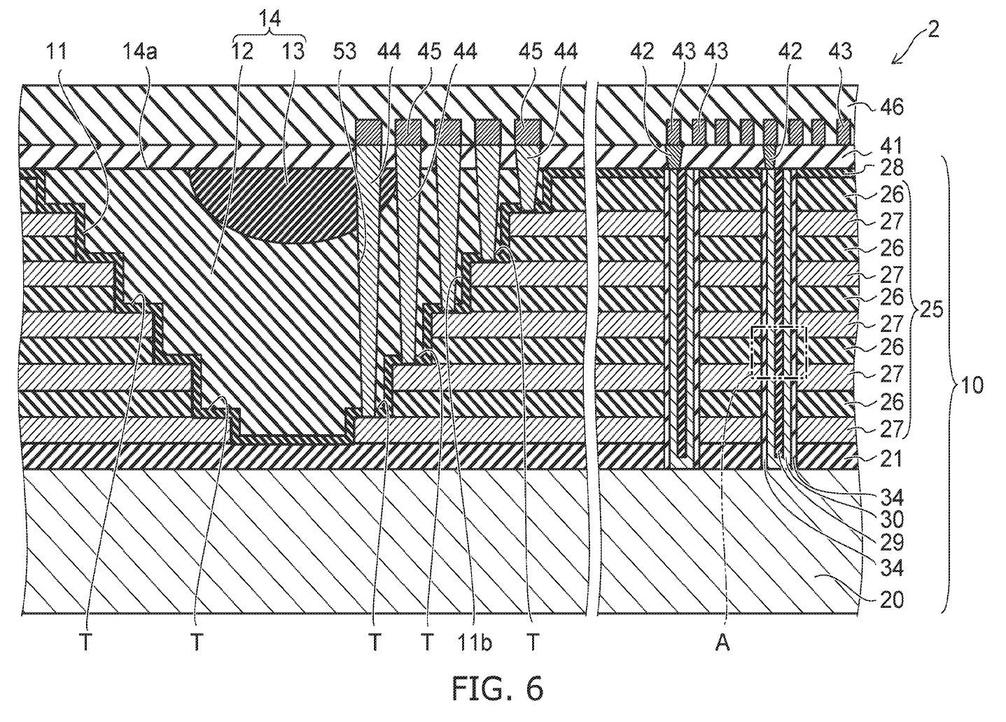

FIG. 6 is a cross-sectional view showing an integrated circuit device according to the embodiment.

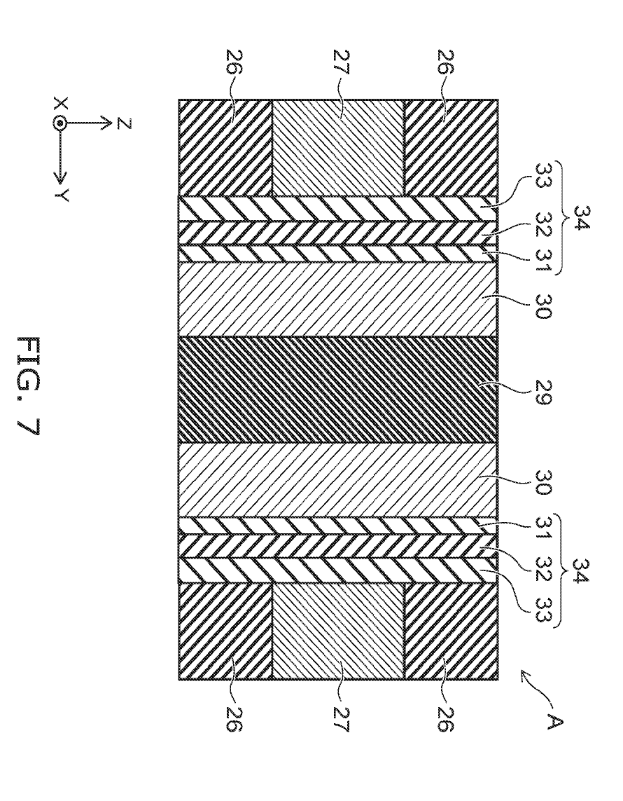

FIG. 7 is a cross-sectional view showing region A of FIG. 6.

The embodiment is a specific example of the first embodiment and is an example in which the first embodiment is applied to a stacked semiconductor memory device. In other words, the integrated circuit device according to the embodiment is a stacked semiconductor memory device.

In the integrated circuit device 2 according to the embodiment as shown in FIG. 6, a silicon substrate 20, a silicon oxide film 21, a stacked body 25, and an etching stopper film 28 are provided in the foundation member 10.

The configuration of the foundation member 10 will now be described in detail.

The silicon substrate 20 is provided in the foundation member 10. The silicon oxide film 21 is provided on the silicon substrate 20. The stacked body 25 is provided on the silicon oxide film 21. In the stacked body 25, for example, electrode layers 27 that are made of a conductive member such as tungsten, polysilicon, etc., are stacked alternately with insulating layers 26 that are made of an insulating material such as silicon oxide, etc. In the stacked body 25, the electrode layers 27 adjacent to each other above and below may be insulated from each other by making voids as the insulating layers 26.

The recess 11 is made in the stacked body 25. The configuration of the side surface 11b of the recess 11 is a stairstep configuration in which terraces T are formed for each pair made of one insulating layer 26 and one electrode layer 27. The etching stopper film 28 that is made of, for example, silicon nitride is provided on the upper surface of the stacked body 25 and on the inner surface of the recess 11.

On the other hand, similarly to the first embodiment described above, the silicon oxide film 12 and the silicon oxide film 13 are provided in the inter-layer insulating film 14.

Other than the foundation member 10 and the inter-layer insulating film 14, a core member 29, a silicon pillar 30, a memory film 34, a silicon oxide film 41, a plug 42, a bit line 43, a contact 44, an upper layer word line 45, and a silicon oxide film 46 are provided in the integrated circuit device 2.

The configuration of the portions of the integrated circuit device 2 other than the foundation member 10 and the inter-layer insulating film 14 will now be described in detail.

The silicon pillar 30 that extends in the Z-direction and pierces the etching stopper film 28, the stacked body 25, and the silicon oxide film 21 is provided inside the stacked body 25. The configuration of the silicon pillar 30 is a cylindrical configuration of which the lower end is plugged. The lower end of the silicon pillar 30 is connected to the silicon substrate 20. The core member 29 that is made of silicon oxide is provided in the interior of the silicon pillar 30. The memory film 34 that can store charge is provided between the silicon pillar 30 and the electrode layer 27 and between the silicon pillar 30 and the insulating layer 26. In the integrated circuit device 2, a memory cell transistor that includes the memory film 34 is configured at each intersection between the silicon pillars 30 and the electrode layers 27.

As shown in FIG. 7, a tunneling insulating film 31, a charge storage film 32, and a blocking insulating film 33 are stacked in the memory film 34 in this order from the silicon pillar 30 side toward the electrode layer 27 side. Although the tunneling insulating film 31 normally is insulative, the tunneling insulating film 31 is a film in which a tunneling current flows when a prescribed voltage within the range of the drive voltage of the semiconductor memory device is applied. The tunneling insulating film 31 is, for example, a single-layer silicon oxide film or an ONO film in which a silicon oxide layer, a silicon nitride layer, and a silicon oxide layer are stacked in this order. The charge storage film 32 is a film that can store charge, is formed of a material having trap sites of electrons, and is formed of, for example, silicon nitride. The blocking insulating film 33 is a film in which a current substantially does not flow even when a voltage within the range of the drive voltage of the semiconductor memory device is applied. The blocking insulating film 33 is, for example, a single-layer silicon oxide film or a multilayer film in which a silicon oxide layer is stacked with a metal oxide layer such as an aluminum oxide layer, a hafnium oxide layer, etc.

As shown in FIG. 6, the silicon oxide film 41 is provided on the foundation member 10 and the inter-layer insulating film 14. The plugs 42 are provided in the regions directly above the silicon pillars 30 inside the silicon oxide film 41. The contacts 44 that extend in the Z-direction and pierce the silicon oxide film 41, the inter-layer insulating film 14, and the etching stopper film 28 are provided in the region directly above one side surface 11b of the recess 11. The contacts 44 are provided at every terrace T; and the lower end of each contact 44 is connected to the portion of each electrode layer 27 of the terrace T.

The multiple bit lines 43 that extend in the X-direction are provided on the silicon oxide film 41. The bit lines 43 are connected to the upper ends of the silicon pillars 30 via the plugs 42. Also, the multiple upper layer word lines 45 that extend in, for example, the X-direction are provided on the silicon oxide film 41. The upper layer word lines 45 are connected to the electrode layers 27 via the contacts 44. Further, the silicon oxide film 46 is provided on the silicon oxide film 41 to cover the bit lines 43 and the upper layer word lines 45.

A method for manufacturing the integrated circuit device according to the embodiment will now be described.

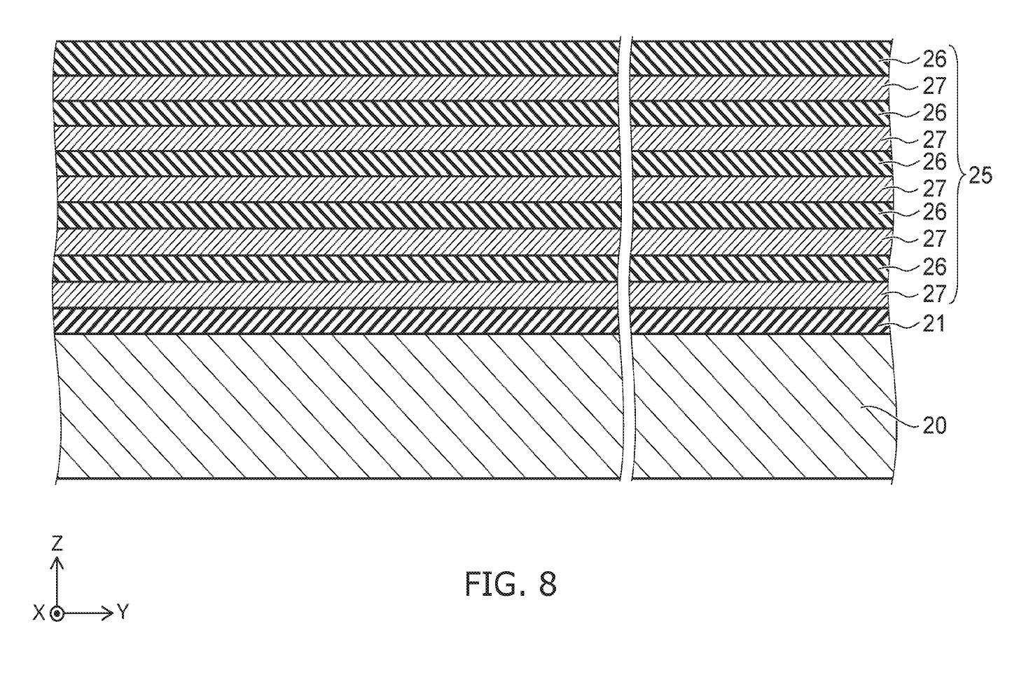

FIG. 8 to FIG. 10 are cross-sectional views showing the method for manufacturing the integrated circuit device according to the embodiment.

First, the silicon substrate 20 is prepared as shown in FIG. 8. Then, the silicon oxide film 21 is formed on the silicon substrate 20. Continuing, the stacked body 25 is formed on the silicon oxide film 21 by alternately stacking the electrode layers 27 as the first layers and the insulating layers 26 as the second layers.

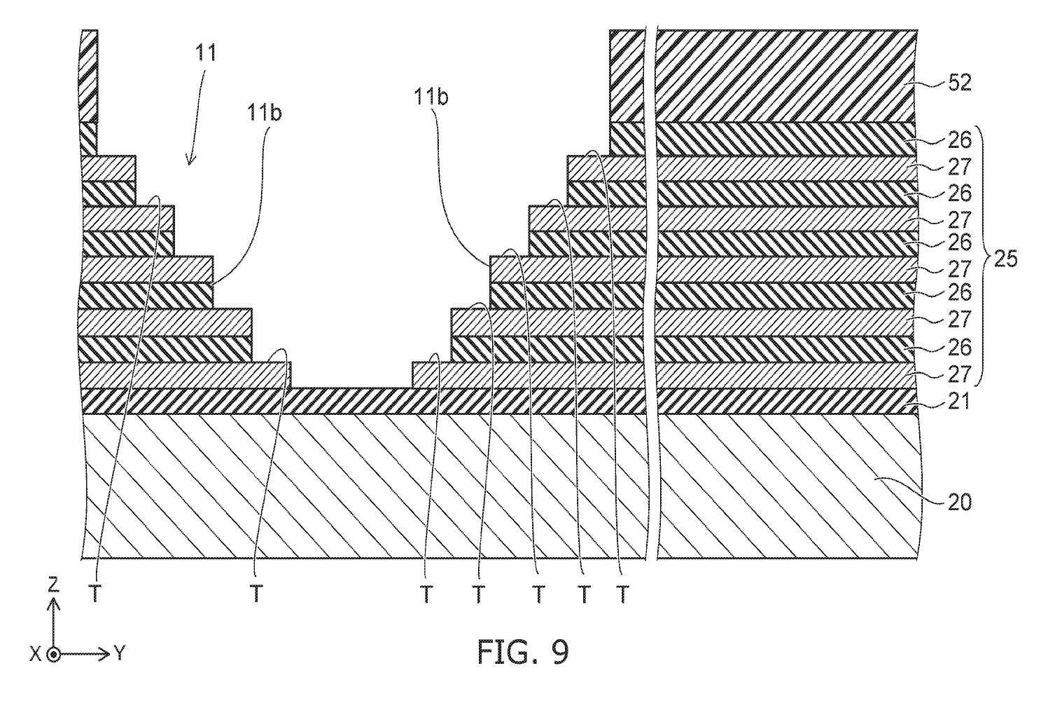

Then, as shown in FIG. 9, a resist film 52 is formed on the stacked body 25. Continuing, the recess 11 that has a valley-like configuration in which the configuration of the side surface 11b is a stairstep configuration is made in the stacked body 25 by forming the terrace T for each pair made of one electrode layer 27 and one insulating layer 26 by alternately repeating slimming of the resist film 52 and etching using the resist film 52 as a mask. The electrode layers 27 are exposed at each terrace T. Subsequently, the resist film 52 is removed.

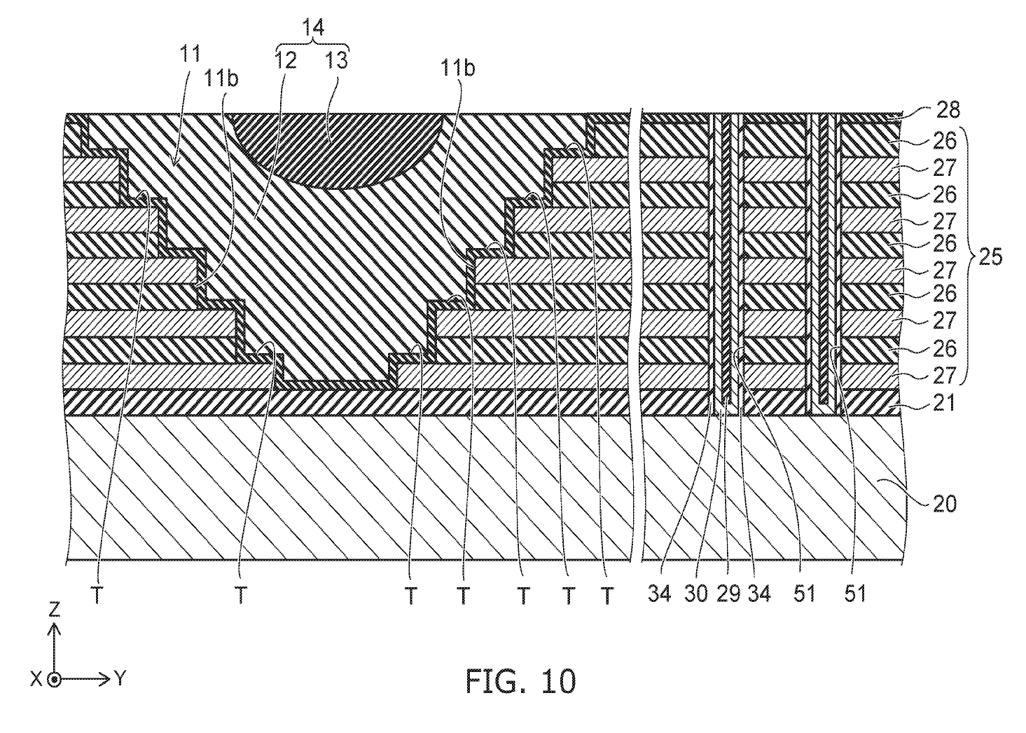

Then, as shown in FIG. 10, the etching stopper film 28 that is made of, for example, silicon nitride is formed to cover the silicon oxide film 21 and the stacked body 25. Thereby, the foundation member 10 is made.

Continuing, the silicon oxide film 12 and the silicon oxide film 13 are formed on the foundation member 10 by the method described in the first embodiment described above; and the inter-layer insulating film 14 is formed inside the recess 11 by performing planarization such as CMP, etc.

Then, memory holes 51 that extend in the Z-direction and reach the silicon substrate 20 are made in the portion of the stacked body 25 other than the recess 11 by performing anisotropic etching such as RIE (Reactive Ion Etching), etc. Continuing, the memory film 34 is formed on the inner surface of the memory hole 51 by forming the blocking insulating film 33, the charge storage film 32, and the tunneling insulating film 31 (referring to FIG. 7) in this order. Then, after removing the memory film 34 that is formed on the bottom surface of the memory hole 51, the silicon pillar 30 is formed on the surface of the memory film 34; and the core member 29 is filled into the silicon pillar 30. The lower end of the silicon pillar 30 is connected to the silicon substrate 20.

Continuing as shown in FIG. 6, the silicon oxide film 41 is formed on the foundation member 10 and the inter-layer insulating film 14 by CVD using, for example, d-TEOS as a source material. Then, contact holes 53 are made by lithography and RIE using the etching stopper film 28 as a stopper. The contact holes 53 extend in the Z-direction and are located in the regions directly above each terrace T in the silicon oxide film 41 and the inter-layer insulating film 14. Continuing, the electrode layers 27 are exposed at the bottom surfaces of the contact holes 53 by removing the etching stopper film 28. Then, the contacts 44 are formed by filling a conductive material such as tungsten, etc., into the contact holes 53. The plugs 42 are formed inside the silicon oxide film 41.

Then, the multiple bit lines 43 that extend in the X-direction and the upper layer word lines 45 that extend in, for example, the X-direction are formed on the silicon oxide film 41. Continuing, the silicon oxide film 46 is formed on the silicon oxide film 41 to bury the bit lines 43 and the upper layer word lines 45 by, for example, performing CVD using d-TEOS as a source material. Thus, the integrated circuit device 2 according to the embodiment is manufactured.

Because the silicon oxide film 13, the silicon oxide film 41, and the silicon oxide film 46 each are formed by CVD using d-TEOS as a source material, there is a possibility that the interface between the silicon oxide film 13 and the silicon oxide film 41 and the interface between the silicon oxide film 41 and the silicon oxide film 46 may not be observed clearly in the cross section shown in FIG. 6. Conversely, because the silicon oxide film 12 is formed by coating, the likelihood is high that the interface between the silicon oxide film 12 and the silicon oxide film 13 is clearly observable.

Effects of the embodiment will now be described.

Because the upper surface 14a of the inter-layer insulating film 14 that is filled into the recess 11 can be substantially flat in the embodiment, for example, the focus of the exposure can be aligned accurately in the lithography for making the contact holes 53. Thereby, the positional precision of the contact holes 53 increases; and the contacts 44 can reach the terraces T reliably. Also, the bit lines 43 and the upper layer word lines 45 can be formed precisely. Due to these effects, the integrated circuit device 2 can be downscaled.

Otherwise, the configuration, the manufacturing method, and the effects of the embodiment are similar to those of the first embodiment described above.

Although an example is illustrated in the second embodiment described above in which the electrode layers 27 and the insulating layers 26 are stacked on the silicon substrate 20, this is not limited thereto; and, for example, the insulating layers 26 and sacrificial films may be stacked on the silicon substrate 20; the silicon pillars 30 and the memory films 34 may be formed; and subsequently, the sacrificial films may be replaced with the electrode layers 27. For example, the sacrificial films may be formed of silicon nitride. Further, the insulating layers 26 may be formed by replacing sacrificial films; and voids may be made as the insulating layers 26 between the electrode layers 27 adjacent to each other above and below by removing conductive sacrificial films after forming the silicon pillars 30 and the memory films 34.

Although an example is illustrated in the second embodiment described above in which the integrated circuit device is a semiconductor memory device, this is not limited thereto. The first embodiment described above is applicable favorably in the case where a film is filled into a recess made in a foundation member and the recess is large enough that it is difficult to planarize the filled film.

Although an example is illustrated in the first and second embodiments described above in which the configuration of the side surface 11b of the recess 11 is a stairstep configuration, this is not limited thereto; and the side surface of the recess may be an oblique surface or a perpendicular surface. However, the first and second embodiments described above are applicable particularly favorably in the case where the side surface of the recess has a stairstep configuration or is an oblique surface.

For example, as technology that is different from the embodiments described above, it also may be considered to obtain a flat surface by sequentially forming a polishing stopper film, a filling film, and a low polishing rate film on the entire surface of the substrate having an unevenness formed in the upper surface and by polishing these films. In this technology, a flat surface is formed from the polishing stopper film of the protrusion and the low polishing rate film of the recess by forming the filling film to have a thickness such that the surface of the polishing stopper film of the protrusion and the surface of the low polishing rate film of the recess are at the same height and by subsequently removing the low polishing rate film and the filling film by polishing. However, in such a case, it is necessary to strictly control the film thickness of the filling film filled into the recess; and because the film thickness of the filling film fluctuates and is dependent on the configuration of the recess, it is difficult to control the film thickness of the filling film to be a prescribed value regardless of the tilt angle of the side surface of the recess in the case where the side surface of the recess has a stairstep configuration or is an oblique surface.

Conversely, according to the first and second embodiments described above, because it is sufficient to form the silicon oxide film 12 of the lower layer as the filling film to a position lower than the upper surface 10a of the foundation member 10 in one section of the region directly above the recess 11 of the foundation member 10 and to deposit the silicon oxide film 13 of the upper layer to be higher than the upper surface 10a of the foundation member 10 in the entire region directly above the recess 11 of the foundation member 10, the positions of the surfaces of the silicon oxide film 12 and the silicon oxide film 13 can be controlled more stably than in the case where the filling film is formed to be equal to a prescribed height.

According to the embodiments described above, an integrated circuit device having high shape precision and a method for manufacturing the same can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing an integrated circuit device, comprising:
forming a first film on a foundation member, a recess being made in a surface of the foundation member, an upper surface of one section of a portion of the first film disposed in a region directly above the recess being positioned lower than an upper surface of a portion of the foundation member at a periphery of the recess;
forming a second film on the first film, an upper surface of the entire portion of the second film disposed in the region directly above the recess being positioned higher than the upper surface of the portion of the foundation member at the periphery of the recess; and
removing portions of the second film and the first film positioned higher than the upper surface of the portion of the foundation member at the periphery of the recess by performing planarization of the second film and the first film on a condition causing a polishing rate of the first film to be higher than a polishing rate of the second film.

2. The method according to claim 1, wherein the first film and the second film include silicon oxide.

3. The method according to claim 2, wherein a carbon concentration of the second film is higher than a carbon concentration of the first film.

4. The method according to claim 3, wherein the carbon concentration of the first film is lower than 1×10²⁰ atoms/cm³, and the carbon concentration of the second film is higher than 1×10²⁰ atoms/cm³.

5. The method according to claim 1, wherein the first film is formed by coating, and the second film is formed by chemical vapor deposition.

6. The method according to claim 1, wherein the first film is formed by coating using polysilazane as a material.

7. The method according to claim 1, wherein the second film is formed by chemical vapor deposition using TEOS as a source material.

8. The method according to claim 1, wherein the planarization is chemical mechanical polishing.

9. The method according to claim 1, wherein a distance between upper end portions of the recess in a first direction is longer than a length of a bottom surface of the recess in the first direction.

10. The method according to claim 1, wherein a side surface of the recess has a stairstep configuration.

11. The method according to claim 1, further comprising:
making a stacked body above a substrate, first layers and second layers being stacked alternately in the stacked body;
forming the foundation member by making the recess in the stacked body, a configuration of a side surface of the recess being a stairstep configuration having terraces each of which is formed for each of the first layers;
making a hole in the stacked body;
forming a memory film on an inner surface of the hole;
forming a semiconductor pillar on a surface of the memory film; and
forming a contact piercing an inter-layer insulating film, the inter-layer insulating film including the first film and the second film subjected to the planarization, a lower end of the contact being connected to one of the terraces.

12. A method for manufacturing an integrated circuit device, comprising:
making a foundation member having a recess made in a surface of the foundation member by forming a stacked body above a substrate and patterning one section of the stacked body into a stairstep configuration, first layers and second layers being stacked alternately in the stacked body, a terrace being formed for each of the first layers in the stairstep configuration;
forming a first silicon oxide film on the foundation member and causing an upper surface of one section of a portion of the first silicon oxide film disposed in a region directly above the recess to be positioned lower than an upper surface of a portion of the foundation member at a periphery of the recess;
forming a second silicon oxide film on the first silicon oxide film and causing an upper surface of the entire portion of the second silicon oxide film disposed in the region directly above the recess to be positioned higher than the upper surface of the portion of the foundation member at the periphery of the recess; and
removing portions of the second silicon oxide film and the first silicon oxide film positioned higher than the upper surface of the portion of the foundation member at the periphery of the recess by performing planarization of the second silicon oxide film and the first silicon oxide film on a condition causing a polishing rate of the first silicon oxide film to be higher than a polishing rate of the second silicon oxide film.

13. The method according to claim 12, further comprising forming a contact piercing an inter-layer insulating film, the inter-layer insulating film including the first silicon oxide film and the second silicon oxide film subjected to the planarization, a lower end of the contact being connected to the terrace.

14. The method according to claim 12, wherein the first silicon oxide film is formed by coating, and the second silicon oxide film is formed by chemical vapor deposition.

15. The method according to claim 12, further comprising:
making a hole in the stacked body; and
forming a semiconductor pillar inside the hole and forming a memory film between the semiconductor pillar and the first layer and between the semiconductor pillar and the second layer.

16. An integrated circuit device, comprising:
a substrate;
a stacked body provided above the substrate, electrode layers and insulating layers being stacked alternately in the stacked body, a recess being made in a surface of the stacked body, a configuration of a side surface of the recess being a stairstep configuration having terraces each of which is formed for each of the electrode layers; and
an inter-layer insulating film filling the recess, the inter-layer insulating film including a first silicon oxide film and a second silicon oxide film, the first silicon oxide film being provided inside the recess, the second silicon oxide film being provided on a central portion of the first silicon oxide film inside the recess, a carbon concentration of the second silicon oxide film being higher than a carbon concentration of the first silicon oxide film.

17. The device according to claim 16, further comprising a contact piercing the inter-layer insulating film, a lower end of the contact being connected to one of the terraces of the electrode layers.

18. The device according to claim 16, wherein a carbon concentration of the first silicon oxide film is lower than 1×10²⁰ atoms/cm³, and a carbon concentration of the second silicon oxide film is higher than 1×10²⁰ atoms/cm³.

19. The device according to claim 16, further comprising:
a semiconductor pillar piercing the stacked body; and
a memory film provided between the semiconductor pillar and the electrode layer.

20. The device according to claim 16, further comprising a silicon nitride film covering an inner surface of the recess.
